(19) United States
(12) Patent Application Publication
(10) Pub. No.: US 2026/0123119 A1
(43) Pub. Date: Apr. 30, 2026

(54) SEMICONDUCTOR LIGHT-EMITTING ELEMENT

(71) Applicant: STANLEY ELECTRIC CO., LTD., Tokyo (JP)

(72) Inventor: Jun NORIMATSU, Tokyo (JP)

(73) Assignee: STANLEY ELECTRIC CO., LTD., Tokyo (JP)

(21) Appl. No.: 19/368,051

(22) Filed: Oct. 24, 2025

(30) Foreign Application Priority Data
Oct. 24, 2024 (JP) 2024-187390

(51) Int. Cl. H10H 20/855; H10H 20/825

(52) U.S. Cl. CPC H10H 20/855; H10H 20/825

(57) ABSTRACT

The present invention provides a semiconductor light-emitting element with high external light extraction efficiency and excellent element characteristics featuring high efficiency and high output. The semiconductor light-emitting element includes: a substrate; a stacked light-emitting semiconductor layer formed on the substrate in order of a first semiconductor layer, an active layer, and a second semiconductor layer; and a light extraction structure formed on a rear surface of the substrate. The light extraction structure is constituted of a waveguide layer formed on the rear surface of the substrate and an uneven structure formed on the waveguide layer, and a refractive index of the waveguide layer is greater than a refractive index of the substrate.

### BACKGROUND OF THE INVENTION

### Field of the Invention

The present invention relates to a semiconductor light-emitting element.

### Description of the Related Art

Conventionally, to improve light extraction efficiency of a light-emitting diode (LED), it has been common practice to provide an uneven structure on a light extraction surface.

For example, Domestic Re-publication of PCT International Application No. WO 2015-016150 discloses a periodic uneven structure formed on a light extraction surface and a fine uneven structure formed on a surface of the periodic uneven structure.

However, in the conventional art, most light entering the uneven structure at angles equal to or exceeding a critical angle is reflected, resulting in low light extraction efficiency, and there is room for further improvement.

The present invention has been made in consideration of the problem described above and provides a semiconductor light-emitting element with high external light extraction efficiency and excellent element characteristics featuring high efficiency and high output.

### SUMMARY OF THE INVENTION

A semiconductor light-emitting element according to one embodiment of the present invention includes:
a substrate;
a stacked light-emitting semiconductor layer formed on the substrate in order of a first semiconductor layer, an active layer, and a second semiconductor layer; and
a light extraction structure formed on a rear surface of the substrate, wherein
the light extraction structure is constituted of a waveguide layer formed on the rear surface of the substrate and an uneven structure formed on the waveguide layer, and
a refractive index of the waveguide layer is greater than a refractive index of the substrate.

A semiconductor light-emitting element according to another embodiment of the present invention includes:
a substrate;
a waveguide layer formed on the substrate;
a stacked light-emitting semiconductor layer formed on the waveguide layer in order of a first semiconductor layer, an active layer, and a second semiconductor layer; and
a light extraction structure formed on a rear surface of the first semiconductor layer, wherein
the light extraction structure is constituted of
an uneven structure formed on the waveguide layer-side of the substrate, the uneven structure having a plurality of periodically arranged depressions and being formed so that the waveguide layer is embedded in the plurality of depressions, and
a refractive index of the waveguide layer is greater than a refractive index of the substrate.

A semiconductor light-emitting element according to another embodiment of the present invention includes:
a substrate;
a stacked light-emitting semiconductor layer formed on the substrate in order of a first semiconductor layer, an active layer, and a second semiconductor layer; and
a light extraction structure formed on the second semiconductor layer, wherein
the light extraction structure is constituted of a waveguide layer formed on the second semiconductor layer and an uneven structure formed on the waveguide layer, and
a refractive index of the waveguide layer is greater than a refractive index of the second semiconductor layer.

### BRIEF DESCRIPTION OF THE DRAWINGS

FIG. 1 is a sectional view schematically showing a structure of a semiconductor light-emitting element 10 according to a first embodiment of the present invention;

FIG. 2 is a plan view of the semiconductor light-emitting element as seen from a side of an uneven structure;

FIG. 3 is a sectional view schematically showing propagation and diffraction of light in a light extraction structure constituted of a waveguide layer and an uneven structure;

FIG. 4A is a sectional view schematically showing a waveguide layer and an uneven structure according to Example 1 (EX1) of the first embodiment;

FIG. 4B is a sectional view schematically showing a projection of the uneven structure;

FIG. 5 is a sectional view schematically showing a light extraction structure according to a comparative example (CX1) having an uneven structure (projection structure) on a substrate surface;

FIG. 6 is a graph showing total transmittance T relative to a refractive index n of a light extraction structure:

FIG. 7 is a graph showing a simulation result of total transmittance T relative to an unevenness period;

FIG. 8 is a sectional view schematically showing a semiconductor light-emitting element according to Example 2 of the first embodiment;

FIG. 9 is a sectional view schematically showing a semiconductor light-emitting element according to Example 3 of the first embodiment; and

FIG. 10 is a sectional view schematically showing a structure of a semiconductor light-emitting element according to a second embodiment.

### DETAILED DESCRIPTION OF THE INVENTION

While preferred embodiments of the present invention will be described below, the embodiments may be modified or combined as appropriate. In addition, in the following description and the attached drawings, substantially identical or equivalent parts will be designated by the same reference signs.

### FIRST EMBODIMENT

### 1. Structure of Semiconductor Light-Emitting Element

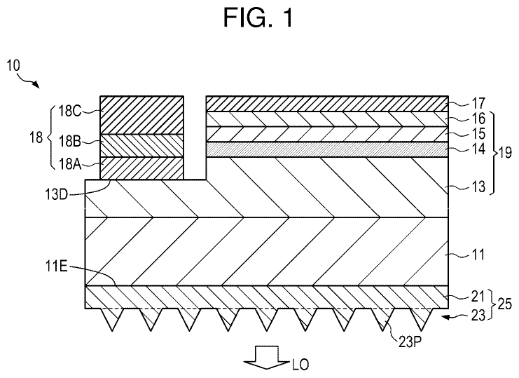

FIG. 1 is a sectional view schematically showing a structure of a semiconductor light-emitting element 10 according to a first embodiment of the present invention. A case where the semiconductor light-emitting element 10 is a deep ultraviolet light-emitting diode (LED) will be described as an example.

As shown in FIG. 1, the semiconductor light-emitting element 10 includes a flat plate-like substrate 11 constituted of a single crystal of AlN, and using the substrate 11 as a growth substrate, an n-type semiconductor layer 13 that is a first semiconductor layer, an active layer 14, and a second semiconductor layer constituted of a p-type semiconductor layer 15 and a p-contact layer 16 are stacked and formed on a surface of the substrate 11 by epitaxial growth. Note that the second semiconductor layer has an opposite conductivity type to the first semiconductor layer. In addition, the second semiconductor layer need not include a contact layer.

While a case where the semiconductor light-emitting element 10 is constituted of an AlGaN-based semiconductor layer will be described below, the semiconductor light-emitting element 10 is not limited thereto. In other words, the semiconductor light-emitting element 10 is not limited to an ultraviolet light-emitting diode and may be a visible light-emitting diode or an infrared light-emitting diode.

First, although the substrate 11 is not particularly limited, a substrate with low dislocation density is preferably used as the substrate 11. The dislocation density of the substrate 11 is preferably 10⁶ cm⁻² or lower and more preferably 10⁴ cm⁻² or lower. Using an AlN substrate with low dislocation density enables dislocation density of semiconductor layers stacked on the substrate 11 to be also lowered and, consequently, luminous efficiency or light reception efficiency can be improved.

In the present embodiment, a crystal growth surface of the substrate 11 is the C-plane. Alternatively, the crystal growth surface of the substrate 11 may be a surface slightly tilted (offset) from the C-plane, in which case an offset angle preferably ranges from 0.1 to 0.5° and more preferably ranges from 0.3 to 0.4°.

The substrate 11 preferably exhibits high permeability with respect to light emitted by the light-emitting element that is ultimately formed. Therefore, an absorption coefficient in the deep ultraviolet region or, more specifically, at wavelengths of 210 nm or more, is preferably 25 cm⁻¹ or less. While a lower limit of the absorption coefficient is preferably 0 cm⁻¹, when industrial production and measurement accuracy are taken into consideration, the lower limit value of the absorption coefficient at 210 nm is 15 cm⁻¹ and the lower limit value of the absorption coefficient at wavelengths of 250 nm or more is 5 cm⁻¹. Using an AlN substrate with such a low absorption coefficient enables degradation of characteristics due to ultraviolet light absorption within the substrate 11 to be suppressed.

In addition, a thickness of the substrate 11 used in the present embodiment is not particularly limited. If the substrate 11 is thin, an amount of light absorbed within the substrate can be kept low even when the absorption coefficient is high. However, if the substrate 11 is too thin, it becomes difficult to handle and may cause the yield of the element to decline. Therefore, usually, the thickness preferably ranges from 50 to 1000 μm.

While the crystal growth surface of the substrate 11 is the C-plane (C+ plane), the crystal growth surface is not limited thereto and, for example, the crystal growth surface may be a C− (C minus) plane, a M-plane, or a A-plane.

In addition, a buffer layer may be provided between the substrate 11 and the n-type semiconductor layer 13. Although the buffer layer is not functionally essential for the semiconductor light-emitting device, a buffer layer is desirably provided from the perspective of suppressing lattice relaxation in the n-type semiconductor layer 13 and thereby improving the yield of the crystal growth process.

In addition, the buffer layer is in a lattice-matched state with the single-crystal substrate 11. In this case, a lattice-matched state refers to a state where a lattice constant of the a-axis of the substrate 11 is substantially equal to the buffer layer and a lattice relaxation rate is ±5% or lower.

Note that materials with high light transmittance such as a sapphire substrate can be used as the substrate 11.

The n-type semiconductor layer 13 is a single-crystal AlxGa1-xN (0.5≤x≤1) layer having a bandgap smaller than that of the substrate 11 and, if a buffer layer is provided, smaller than that of the buffer layer. Since the n-type semiconductor layer 13 is lattice-matched with the substrate 11, lattice relaxation accompanied by dislocation generation has not occurred in the n-type semiconductor layer 13. Therefore, the dislocation density in the n-type semiconductor layer 13 becomes equal to the dislocation density of the surface of the substrate 11. Accordingly, the dislocation density of the n-type semiconductor layer 13 is preferably 10⁶ cm⁻² or lower and more preferably 10⁴ cm⁻² or lower in a similar manner to the substrate 11. Even when the n-type semiconductor layer 13 according to the present invention is formed of a plurality of layers, since the layers are all lattice-matched, the dislocation density is equivalent in each layer. Note that when a sapphire substrate is used as the substrate 11, the buffer layer may be provided on the sapphire substrate. In this case, the dislocation density is greater than when AlN is used as the substrate.

The n-type semiconductor layer 13 contains, for example, Si as an n-type dopant. A dopant concentration of the n-type semiconductor layer 13 is not particularly limited and may be determined as appropriate according to the purpose. In particular, to achieve high conductivity, the Si concentration preferably ranges from 1×10¹⁸ cm⁻³ to 5×10¹⁹ cm⁻³. Even when the n-type semiconductor layer 13 is formed of a plurality of layers, the concentration of Si of each layer preferably ranges from 1×10¹⁸ cm⁻³ to 5×10¹⁹ cm⁻³. In addition, the Si concentration of the respective layers may be constant or the Si concentration may vary from layer to layer depending on device design and other factors. Additionally, the Si concentration can be made relatively high at interfaces between the respective layers.

In addition, in the present embodiment, the n-type semiconductor layer 13 is constituted of an AlGaN layer (composition gradient layer) in which the Al composition decreases in a growth direction or, in other words, a direction of separation from the substrate 11 (toward the active layer 14).

Note that the n-type semiconductor layer 13 may be constituted of a plurality of semiconductor layers with mutually different crystal compositions or impurity concentrations. In addition, the n-type semiconductor layer 13 may contain an undoped layer (or an i-layer).

The semiconductor light-emitting element 10 has the active layer 14 formed on the n-type semiconductor layer 13, the p-type semiconductor layer 15 formed on the active layer 14, and the p-contact layer 16 formed on the p-type semiconductor layer 15. The p-type semiconductor layer 15 functions as a p-type cladding layer.

The active layer 14 is constituted of an AlGaN layer having a bandgap smaller than that of the n-type semiconductor layer 13. In the present embodiment, the active layer 14 has a multiple quantum well (MQW) structure made up of a plurality of well layers and barrier layers. In addition, the active layer 14 emits light in the deep ultraviolet region. Note that the configuration of the active layer 14 is not limited thereto and may be constituted of a single layer or may have a single quantum well structure.

An emission wavelength (peak wavelength) of the active layer 14 is preferably within a range of 200 to 360 nm, more preferably 200 to 300 nm, and even more preferably 200 nm to 280 nm.

The p-type semiconductor layer 15 is constituted of an AlN layer or an AlGaN layer that contains, for example, Mg as a p-type dopant. Note that the p-type semiconductor layer 15 may be constituted of a plurality of semiconductor layers with mutually different crystal compositions or impurity concentrations. In addition, the p-type semiconductor layer 15 may contain an undoped layer (or an i-layer). Furthermore, an electron blocking layer may be provided between the active layer 14 and the p-type semiconductor layer 15.

A p-electrode 17 is provided on the p-contact layer 16. The p-electrode 17 is constituted of, for example, a laminate of a Ni layer and an Au layer. The p-electrode 17 may be provided with a reflective layer and the reflective layer is preferably provided over the entire surface of the p-electrode 17.

An exposed portion (exposed surface 13D) of the n-type semiconductor layer 13 is formed by partially removing the semiconductor layer (stacked light-emitting semiconductor layer 19) in which the n-type semiconductor layer 13, the active layer 14, the p-type semiconductor layer 15, and the p-contact layer 16 are stacked on the substrate 11 in this order so as to expose the n-type semiconductor layer 13.

An n-electrode 18 is formed on the exposed surface 13D of the n-type semiconductor layer 13 (n-electrode formation region). The n-electrode 18 is constituted of an ohmic contact metal layer 18A (for example, a Ti layer with a layer thickness of 1 nm) with the n-type semiconductor layer 13, an electrode layer 18B (for example, an Al layer with a layer thickness of 250 nm) formed on the ohmic contact metal layer 18A, and a pad electrode 18C (for example, with a layer thickness of 1.5 μm) formed on the electrode layer 18B and made of Au.

The active layer 14 emits light when voltage is applied between the p-electrode 17 and the n-electrode 18.

### 2. Light Extraction Structure of Semiconductor Light-Emitting Element

### (1) Light Extraction Structure

As shown in FIG. 1, a light extraction structure 25 is provided on a rear surface 11E of the substrate 11 (a surface opposite to the side where the stacked light-emitting semiconductor layer 19 is stacked). The light extraction structure 25 is constituted of a waveguide layer 21 provided on the rear surface 11E of the substrate 11 and an uneven structure 23 provided on the waveguide layer 21. Light radiated from the active layer 14 and extracted from the light extraction structure 25 is radiated outward (air) (output light LO).

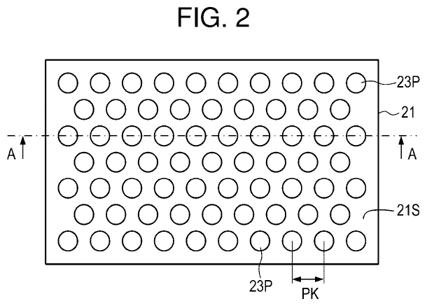

FIG. 2 is a plan view of the semiconductor light-emitting element 10 as seen from a side of the uneven structure 23. The waveguide layer 21 has a flat plate shape and has a constant layer thickness, and the uneven structure 23 is constituted of a plurality of fine projections 23P arranged on the waveguide layer 21. More specifically, in the uneven structure 23, the plurality of projections 23P are arranged in a triangular lattice array in which each projection 23P is arranged at a triangular lattice point with a period of PK. Note that a surface 21S of the waveguide layer 21 is exposed between adjacent projections 23P where a projection 23P is not provided.

Note that the plurality of projections 23P are preferably periodically arranged in a triangular lattice array, a square lattice array, an hexagonal lattice array, or the like, and most preferably arrayed in a triangular lattice array that has a maximum filling factor. Note that the plurality of projections 23P need not be periodically arranged and may be randomly arranged.

The waveguide layer 21 is made of a material with a greater refractive index than the substrate 11. When the substrate 11 is an AlN substrate (refractive index 2.3), for example, Zro₂ with a refractive index of 2.6 that is a greater refractive index than AlN can be used as the waveguide layer 21.

Alternatively, when a sapphire substrate (refractive index 1.8) is used as the substrate 11, for example, SiN, HfO₂, or the like with a refractive index of 2.3 or Zro₂ with a refractive index of 2.6 can be used as the waveguide layer 21.

While the waveguide layer 21 and the plurality of fine projections 23P that constitute the uneven structure 23 may be made of a same material, the plurality of fine projections 23P that constitute the uneven structure 23 may be made of a material with a different refractive index from the waveguide layer 21.

### (2) Manufacturing of Light Extraction Structure

The light extraction structure 25 that is constituted of the waveguide layer 21 and the uneven structure 23 can be fabricated using known methods. For example, high-refractive-index layers such as ZrO₂ and HfO₂ can be deposited using an atomic layer deposition (ALD) apparatus, a sputtering apparatus, or a CVD apparatus. For the uneven structure 23, methods such as electron beam lithography, optical lithography, and nanoimprint lithography can be applied.

Furthermore, as etching methods, dry etching methods such as inductively coupled plasma (ICP) etching and reactive ion etching (RIE), or wet etching methods using acidic or alkaline solutions as etching liquids, can be applied. In this case, dry etching is preferably used in order to form patterns with high periodicity.

### (3) Light Extraction Structure Constituted of Waveguide Layer and Uneven Structure

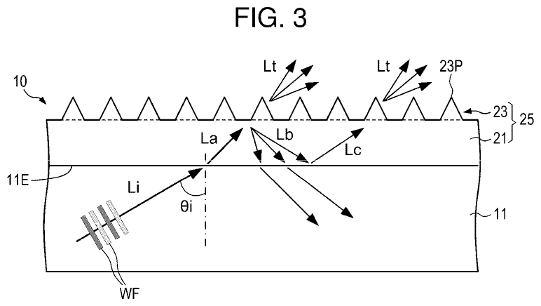

FIG. 3 is a sectional view schematically showing propagation and diffraction of light in the light extraction structure 25 constituted of the waveguide layer 21 and the uneven structure 23.

Incident light Li having entered the rear surface 11E of the substrate 11 which is the interface between the substrate 11 and the waveguide layer 21 at an angle of incidence θi propagates within the waveguide layer 21 (incident light La). Note that while a trajectory of light is illustrated by arrows, this does not imply that it can be approximated by geometric optics and merely illustrates directions perpendicular to a wavefront WF of the light.

The incident light La propagating within the waveguide layer 21 is diffracted and scattered by the uneven structure 23 and diffracted light is generated in a plurality of directions. Here, the diffracted light reflected back toward the substrate 11 will be referred to as reflected diffracted light Lb while the diffracted light emitted outward (into air) will be referred to as transmitted diffracted light Lt.

A portion of the reflected diffracted light Lb undergoes total reflection at the interface between the substrate 11 (AlN) and the waveguide layer 21 (in other words, the rear surface 11E of the substrate 11), and the totally-reflected propagating light Lc propagates within the waveguide layer 21. The propagating light Lc once again enters the uneven structure 23 and a part of the propagating light Lc is radiated outward as the transmitted diffracted light Lt. Therefore, transmittance to the outside (into air) of the incident light Li to the light extraction structure 25 can be improved, thereby improving the light extraction efficiency.

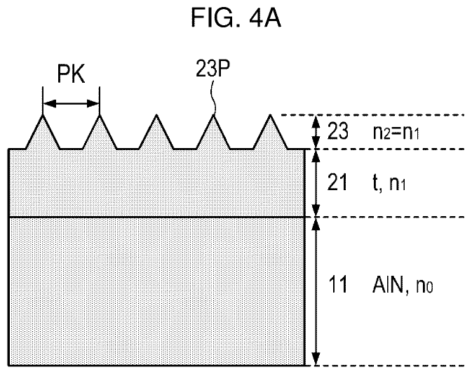

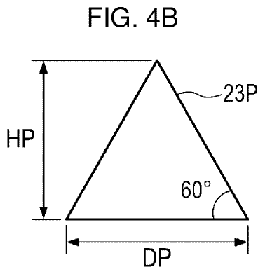

FIG. 4A is a sectional view schematically showing the waveguide layer 21 and the uneven structure 23 according to Example 1 (EX1) of the first embodiment, and FIG. 4B is a sectional view schematically showing the projection 23P of the uneven structure 23. Hereinafter, a result of a simulation performed based on the structure shown in FIGS. 4A and 4B will be described.

Specifically, the uneven structure 23 has a plurality of conical projections 23P. An inclination angle of a side surface of the conical projection 23P is, for example, 60°. The substrate 11 (AlN) has a refractive index n0 of 2.3, and the waveguide layer 21 and the plurality of projections 23P of the uneven structure 23 are formed of Zro₂ with a refractive index n1=n2 of 2.6. The layer thickness t of the waveguide layer 21 is 127 nm. In addition, the plurality of projections 23P are arranged at triangular lattice point positions with a period PK of 600 nm. Each projection 23P is a conical projection, and the simulation was performed using a base diameter DP of 500 nm and a height HP of 433 nm.

### (a) Transmission/Diffraction by Uneven Structure

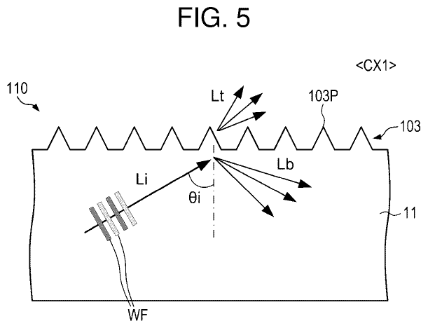

FIG. 5 is a sectional view schematically showing a light extraction structure according to a comparative example (CX1) having an uneven structure (projection structure) on a substrate surface.

More specifically, an uneven structure 103 is provided on the surface of the substrate 11 (AlN). Unlike the light extraction structure 25 according to the present embodiment, the waveguide layer 21 is not provided between the substrate 11 and the uneven structure 103. In other words, simply, the surface of the substrate 11 has fine unevenness and projections 103P of the uneven structure 103 are made of the same AlN as the substrate 11.

Note that the shape, the size, the arrangement, and the like of the projections 103P are the same as those of the projections 23P according to Example 1 (EX1).

The diffraction angles of all diffracted light diffracted by the uneven structure 103 according to the comparative example (CX1) are calculated using the following Equation (1).

$$Λ [ {n}_{d} sin ( {θ}_{d} ) - {n}_{i} sin ( {θ}_{i} ) ] = {m}_{g} λ , {m}_{g} = 0 , \pm 1 , \pm 2 , … , \qquad Eq . ( 1 )$$

Λ: lattice period
nᵢ: refractive index of medium through which incident light propagates
n^{d}: refractive index of medium through which diffracted light propagates
θᵢ: angle of incidence of light
θ_{d}: diffraction angle
m_{g}: diffraction order

Note that λ denotes wavelength in a vacuum. In addition, the lattice period Λ here is a period that can be regarded as the diffraction grating for the light extraction structure 25 in all azimuth angles and differs from the period PK of the projections 23P.

Under the above conditions, a simulation of reflected diffracted light and transmitted diffracted light was performed using the three-dimensional finite difference time domain (FDTD) method. Note that the simulation was performed with the incident angle θi fixed at 60°.

Diffraction and scattering occur due to the uneven structure 103, allowing some light to pass through into the air. The simulation results showed that the energy of light propagating into the air accounted for approximately 10.8% of the total incident energy. The majority of the remaining energy is reflected and propagates toward the substrate 11 (AlN) side. By effectively utilizing this reflected light (reflected diffracted light and reflected scattered light), it is possible to improve transmittance.

Meanwhile, when a similar simulation was performed on the light extraction structure 25 according to Example 1 (EX1), the energy of light propagating into the air accounted for approximately 13.8% of the total incident energy.

Specifically, an improvement of approximately 1.28 times was achieved compared to the 10.8% of the comparative example (CX1).

As described with reference to FIG. 3, since the propagating light Lc reflected toward the substrate 11 side by the uneven structure 23 and totally reflected at the interface between the substrate 11 (AlN) and the waveguide layer 21 re-enters the uneven structure 23 and a portion of the propagating light Lc is then radiated into the air as transmitted diffracted light Lt, the light extraction efficiency can be improved. In other words, by subjecting the diffracted light and the scattered light generated by the uneven structure 23 to total reflection at the interface with the substrate 11 and to multiple reflection inside the waveguide layer 21, the transmitted diffracted light from the uneven structure 23 can be increased, and both transmittance to air from the substrate 11 and the light extraction efficiency can be improved.

### (b) Refractive Index of Light Extraction Structure

Light emission from the active layer 14 radiates in various directions in three-dimensional space. Therefore, it is important that a cumulative value, obtained by summing the transmittance of incident light entering the light extraction structure 25 across the ranges of incident angles θ from 0 to 90° and azimuth angles φ from 0 to 360°, is improved. In the present specification, the cumulative value will be referred to as total transmittance T. The total transmittance T is calculated by Equation (2) below.

$$T = \frac{1}{2 π} {\int }_{0}^{2 π} {\int }_{0}^{π / 2} T \text{(θ, ϕ)sinθ} d θ d ϕ \qquad Eq . ( 2 )$$

For the simulation, the rigorous coupled-wave analysis (RCWA) method was employed, and calculations were performed with the incident angle θ ranging from 0 to 87°, the azimuth angle φ ranging from 0 to 360°, and polarized light of the incident light as s-polarized light. Furthermore, the calculations were performed assuming that the waveguide layer 21 and the uneven structure 23 have the same refractive index.

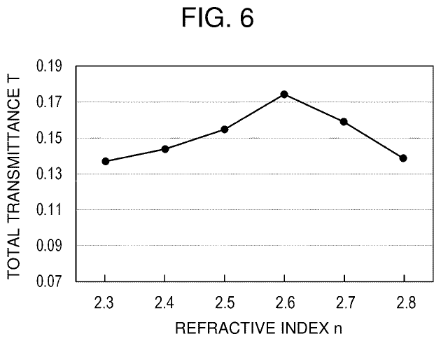

FIG. 6 shows the total transmittance T calculated by using the refractive index n of the waveguide layer 21 and the uneven structure 23 (in other words, the light extraction structure 25) as a parameter and varying n in increments of 1.0 within the range of n=2.3 to 2.8 in the light extraction structure 25 constituted of the waveguide layer 21 and the uneven structure 23 shown in FIGS. 4A and 4B. Note that the total transmittance T in a case of flat AlN and air was 0.07.

The simulation result shows that a high total transmittance T is obtained when the refractive index n of the waveguide layer 21 is greater than the refractive index of the substrate 11 (AlN, refractive index=2.3). Note that the refractive index n of the light extraction structure 25 is preferably within a range of 2.4 to 2.75 which is greater than the refractive index of the substrate 11 by 0.1 to 0.45 and more preferably the refractive index n is within a range of 2.5 to 2.7 which is greater than the refractive index of the substrate 11 by 0.2 to 0.3.

Note that the waveguide layer 21 may be formed of a single layer made of a material with a greater refractive index than the substrate 11 or formed of a multi-layered thin film containing a layer with a greater refractive index than the substrate 11.

### (c) Period of Uneven Structure

When the lattice period in the uneven structure (or projection structure) exceeds a coherence length CL in a vacuum, light loses its coherence and diffraction light ceases to be generated. Here, if wavelength is denoted by λ and half-width at half maximum of the wavelength spectrum is denoted by Δλ, then the coherence length CL is defined as CL=(λ²/Δλ). For example, in the case of a deep ultraviolet light-emitting diode, when wavelength λ=265 nm and Δλ=11 nm, then CL=6.3 μm.

Although the relationship between the in-plane lattice period and the unevenness period (array period) changes due to the array of the periodic uneven structure, since lattice period≤unevenness period is conceivably satisfied, the unevenness period is desirably equal to or less than the coherence length CL in a vacuum. In addition, in the case of a deep ultraviolet light-emitting diode, the coherence length CL is preferably 6.3 μm or less.

Furthermore, if the period of the uneven structure becomes too small, diffraction light ceases to be generated according to Equation (1).

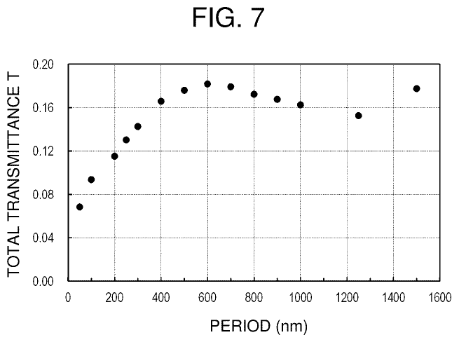

FIG. 7 is a graph showing a simulation result of the total transmittance T relative to a period (array period) PK of the uneven structure shown in FIGS. 4A and 4B. The simulation was performed with a base diameter DP of the conical projection 23P being DP=PK×0.83 and the height HP being HP=PK×0.7.

As shown in FIG. 7, diffraction light satisfying Equation (1) starts to be generated when the period PK of the unevenness is around 50 nm, and the effect becomes more pronounced when the period PK is 100 nm or greater.

In this case, since the optical wavelength (wavelength in medium) is approximately 102 nm (=265 nm/2.6), the simulation result indicates that the period PK of the unevenness is preferably greater than 0.5 times the optical wavelength and more preferably greater than 1 time the optical wavelength.

In addition, the base diameter DP and the height HP of the projection 23P are preferably greater than 0.5 times the wavelength in medium, and more preferably greater than 1 time the wavelength in medium. Furthermore, the diameter DP and the height HP are preferably equal to or less than the coherence length CL in a vacuum.

### (4) Other Examples and Modifications

### (a) Example 2

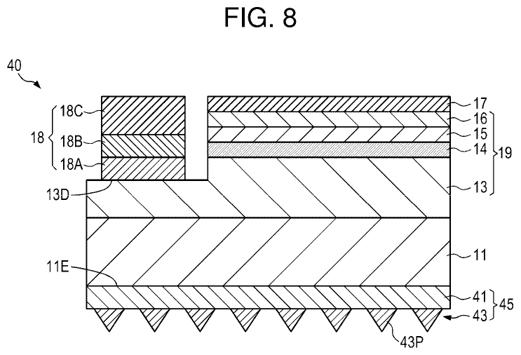

FIG. 8 is a sectional view schematically showing a semiconductor light-emitting element 40 according to Example 2 of the first embodiment. In the semiconductor light-emitting element 40 according to Example 2, a light extraction structure 45 provided on the rear surface of the substrate 11 is constituted of a waveguide layer 41 and an uneven structure 43 provided on the waveguide layer 41. A difference from the semiconductor light-emitting element 10 according to Example 1 is that materials with different refractive indexes are respectively used for the waveguide layer 41 and projections 43P of the uneven structure 43.

For example, ZrO₂ (refractive index: 2.6) can be used for the waveguide layer 41 and, for example, SiO₂, Al₂O₃, SiN, HfO₂, and the like can be used for the uneven structure 43. Note that the waveguide layer 41 need only use a material with a greater refractive index than the substrate 11.

Even in the semiconductor light-emitting element 40 according to Example 2, after being diffracted and scattered by the uneven structure 43, since light that undergoes total reflection at the interface between the waveguide layer 41 and the substrate 11 and returns to the uneven structure 43 is diffracted and scattered once again by the uneven structure 43, light extraction efficiency is improved.

### (b) Example 3

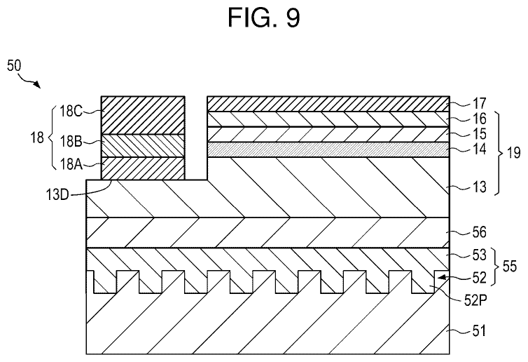

FIG. 9 is a sectional view schematically showing a semiconductor light-emitting element 50 according to Example 3 of the first embodiment. In the semiconductor light-emitting element 50 according to Example 3, a sapphire substrate is used as a substrate 51 and a light extraction structure 55 is provided on the substrate 51.

More specifically, a surface of the substrate 51 has a plurality of depressions periodically arranged at lattice positions. For example, an AlGaN layer with a refractive index greater than that of the substrate 51 (sapphire) is formed on the surface of the substrate 51 on which the plurality of depressions are formed. The plurality of depressions of the substrate 51 are, for example, cylindrical and have the same size. Therefore, the AlGaN embedded in the plurality of depressions of the substrate 51 constitutes an uneven structure 52 made up of a plurality of cylindrical projections 52P arranged at lattice positions, and the AlGaN layer on the substrate 51 constitutes a waveguide layer 53. In other words, the semiconductor light-emitting element 50 has the light extraction structure 55 constituted of the uneven structure 52 and the waveguide layer 53. Note that a shape of the plurality of projections 52P is not limited to a cylindrical shape.

A semiconductor layer 56 made of AlN is formed on the light extraction structure 55, and the n-type semiconductor layer 13, the active layer 14, the p-type semiconductor layer 15, and the p-contact layer 16 are stacked in this order (stacked light-emitting semiconductor layer 19) on the semiconductor layer 56.

Even in the semiconductor light-emitting element 50 according to Example 3, after propagating within the waveguide layer 53 and being diffracted by the uneven structure 52, since light that undergoes total reflection at the semiconductor layer 56 and returns to the uneven structure 52 is diffracted once again by the uneven structure 52, light extraction efficiency is improved.

### (c) Modifications

(i) While cases where the plurality of projections of uneven structures have a conical shape or a cylindrical shape have been described in the examples described above, shapes are not limited thereto. The plurality of projections may have shapes such as a columnar shape, a conical shape, or a truncated conical shape. For example, the plurality of projections may have various shapes such as the shapes of a cone, a truncated cone, a cylinder, a hemisphere, a triangular pyramid, a triangular prism, a truncated triangular pyramid, a hexagonal pyramid, a hexagonal prism, and a truncated hexagonal pyramid. In addition, the uneven structures may randomly contain projections with a plurality of these shapes.

In the present specification, note that the term “conical projections” is not limited to projections having a perfect conical shape but also includes pyramidal projections with a substantially conical lateral surface. In addition, the terms cone, cylinder, truncated cone, and hemisphere include an elliptical cone, an elliptical cylinder, a truncated elliptical cone, and an elliptical sphere. Furthermore, conical and truncated conical projections may have a curved side shape, such as a rounded shape convexly bulging from a conical surface. Note that a base diameter a of a conical projection means a long diameter of the base.

(ii) In the examples described above, when an AlN substrate is used as the substrate, a layer containing at least one of, for example, ZrO₂, AlGAN, and diamond can be used as the waveguide layer.

In addition, when a sapphire substrate is used as the substrate, a layer containing at least one of, for example, HfO₂, SiN, AlN, Zro₂, AlGaN, and diamond can be used as the waveguide layer.

### SECOND EMBODIMENT

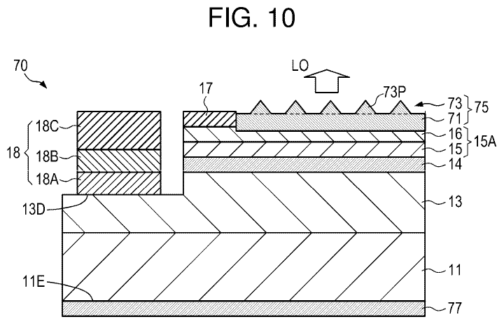

FIG. 10 is a sectional view schematically showing a structure of a semiconductor light-emitting element 70 according to a second embodiment of the present invention.

In the semiconductor light-emitting element 70 according to the second embodiment, a light extraction structure 75 is provided on an opposite side to the substrate 11. Specifically, the light extraction structure 75 constituted of a waveguide layer 71 and an uneven structure 73 having a plurality of projections 73P is formed on a second semiconductor layer 15A. Note that the second semiconductor layer 15A need not include the p-contact layer 16.

More specifically, the p-electrode 17 is formed on a part of the p-contact layer 16 and the light extraction structure 75 is formed in a region outside the formation region of the p-electrode 17. The waveguide layer 71 is formed of a material with a greater refractive index than the p-contact layer 16 or the second semiconductor layer 15A.

In addition, in the present embodiment, a light reflection layer 77 is provided on a rear surface of the substrate 11. The light reflection layer 77 is constituted of a metal layer or the like that exhibits high reflectivity with respect to light emitted from the active layer 14. Therefore, light radiated from the active layer 14 is radiated outward (air) from the light extraction structure 75 (output light LO).

While a case where the light extraction structure 75 is formed on the p-contact layer 16 has been shown, when optical loss in the p-contact layer 16 is significant, the p-contact layer 16 may be partially removed and the light extraction structure 75 may be formed on the p-type semiconductor layer 15 instead.

Additionally, a transparent electrode made of a transparent conductive material such as indium tin oxide (ITO) may be provided on the second semiconductor layer 15A, and the light extraction structure 75 may be formed on the transparent electrode. In this case, the waveguide layer 71 has a greater refractive index than the transparent electrode.

Therefore, after propagating within the waveguide layer 71 and being diffracted by the uneven structure 73, since light that undergoes total reflection at the p-contact layer 16 and returns to the uneven structure 73 is diffracted once again by the uneven structure 73, light extraction efficiency is improved.

As described in detail above, according to the present disclosure, a semiconductor light-emitting element with high external light extraction efficiency and excellent element characteristics featuring high efficiency and high output can be provided.

### REFERENCE SIGNS LIST

10, 40, 50, 70 semiconductor light-emitting element
11, 51 substrate
11E rear surface (interface)
13 n-type semiconductor layer (first semiconductor layer)
13D exposed surface
14 active layer
15 p-type semiconductor layer
15A second semiconductor layer
16 p-contact layer
21, 41, 53, 71 waveguide layer
23, 43, 52, 73 uneven structure
23P, 43P, 52P, 73P projection (projecting portion)
25, 45, 55, 75 light extraction structure
PK: array period

1. A semiconductor light-emitting element, comprising:
a substrate;
a stacked light-emitting semiconductor layer formed on the substrate in order of a first semiconductor layer, an active layer, and a second semiconductor layer; and
a light extraction structure formed on a rear surface of the substrate, wherein
the light extraction structure is constituted of a waveguide layer formed on the rear surface of the substrate and an uneven structure formed on the waveguide layer, and
a refractive index of the waveguide layer is greater than a refractive index of the substrate.

2. The semiconductor light-emitting element according to claim 1, wherein the uneven structure is constituted of a plurality of projections periodically arranged on the waveguide layer.

3. The semiconductor light-emitting element according to claim 2, wherein an arrangement period of the plurality of projections is greater than 0.5 times a wavelength in medium and equal to or less than a coherence length in a vacuum.

4. The semiconductor light-emitting element according to claim 2, wherein the projections of the uneven structure have at least one of the following shapes: a cone, a truncated cone, a cylinder, a hemisphere, a triangular pyramid, a triangular prism, a truncated triangular pyramid, a hexagonal pyramid, a hexagonal prism, and a truncated hexagonal pyramid.

5. The semiconductor light-emitting element according to claim 1, wherein the uneven structure is made of a material that differs from that of the waveguide layer.

6. The semiconductor light-emitting element according to claim 1, wherein
light emission from the active layer has a peak wavelength within a range from 200 to 360 nm,
the substrate is AlN, and
the waveguide layer is constituted of a layer containing at least one of Zro₂, AlGaN, and diamond.

7. A semiconductor light-emitting element, comprising:
a substrate;
a waveguide layer formed on the substrate;
a stacked light-emitting semiconductor layer formed on the waveguide layer in order of a first semiconductor layer, an active layer, and a second semiconductor layer; and
a light extraction structure formed on a rear surface of the first semiconductor layer, wherein
the light extraction structure is constituted of
an uneven structure formed on the waveguide layer-side of the substrate, the uneven structure having a plurality of periodically arranged depressions and being formed so that the waveguide layer is embedded in the plurality of depressions, and
a refractive index of the waveguide layer is greater than a refractive index of the substrate.

8. The semiconductor light-emitting element according to claim 7, wherein
the stacked light-emitting semiconductor layer is constituted of an AlGaN-based semiconductor,
the first semiconductor layer contains an AlN layer formed on the waveguide layer, and
the substrate is made of sapphire and the waveguide layer is made of AlGaN.

9. A semiconductor light-emitting element, comprising:
a substrate;
a stacked light-emitting semiconductor layer formed on the substrate in order of a first semiconductor layer, an active layer, and a second semiconductor layer; and
a light extraction structure formed on the second semiconductor layer, wherein
the light extraction structure is constituted of a waveguide layer formed on the second semiconductor layer and an uneven structure formed on the waveguide layer, and
a refractive index of the waveguide layer is greater than a refractive index of the second semiconductor layer.

10. The semiconductor light-emitting element according to claim 9, wherein the uneven structure is constituted of a plurality of projections periodically arranged on the waveguide layer.

11. The semiconductor light-emitting element according to claim 10, wherein an arrangement period of the plurality of projections is greater than 0.5 times a wavelength in medium and equal to or less than a coherence length in a vacuum.

12. The semiconductor light-emitting element according to claim 9, comprising:
a transparent electrode formed on the second semiconductor layer, wherein
the waveguide layer has a refractive index greater than that of the transparent electrode and is formed on the transparent electrode.
